(19) United States
(12) Patent Application Publication
(10) Pub. No.: US 2025/0062341 A1
(43) Pub. Date: Feb. 20, 2025

(54) SINGLE CRYSTAL DOPED CATHODE MATERIALS FROM RECYCLED LITHIUM-ION BATTERIES

(71) Applicant: Ascend Elements, Inc., Westborough, MA (US)

(72) Inventors: Bohang Song, Westborough, MA (US); Eric Gratz, Westborough, MA (US); Yadong Liu, Westborough, MA (US); Dhiren Mistry, Westborough, MA (US); Jiyong Shin, Westborough, MA (US); Martha Monzon, Westborough, MA (US)

(21) Appl. No.: 18/940,387

(22) Filed: Nov. 7, 2024

Related U.S. Application Data
(63) Continuation-in-part of application No. 18/231,953, filed on Aug. 9, 2023.
(63) Continuation-in-part of application No. 18/120,776, filed on Mar. 13, 2023.
(63) Continuation-in-part of application No. 18/120,786, filed on Mar. 13, 2023.
(60) Provisional application No. 63/697,983, filed on Sep. 23, 2024.
(60) Provisional application No. 63/597,524, filed on Nov. 9, 2023.

(51) Int. Cl. H01M 4/525; B09B 3/70; B09B 3/80; B09B 101/16; C01G 53/00; C30B 29/22; H01M 4/02; H01M 4/505

(52) U.S. Cl. CPC H01M 4/525; B09B 3/70; B09B 3/80; C01G 53/50; C30B 29/22; H01M 4/505; B09B 2101/16; C01P 2002/52; C01P 2004/03; C01P 2004/61; C01P 2006/11; C01P 2006/40; H01M 2004/021

(57) ABSTRACT

In a battery recycling process, a recycling stream including charge material metals from exhausted Li-ion batteries is aggregated or otherwise comminuted to generate recycled battery charge material having comparable or improved cycle life as well as recycled charge material precursor having fewer cracking defects using doping substances in both a coprecipitation phase and a sintering phase of the recycling sequence. Prior to coprecipitation of a cathode material precursor, a leach solution of comingled charge material metals is produced, the ratio of the charge material metals is adjusted based on recycled battery specifications, and a relatively small quantity of a first dopant is added. The doped precursor, a lithium salt, and a second dopant are combined and sintered to form a doped cathode material having a single crystal morphology and a higher tap density than the doped cathode precursor.

### RELATED APPLICATIONS

This patent application is a continuation-in-part (CIP) of U.S. patent application Ser. No. 18/120,776, filed Mar. 13, 2023, entitled, “DOPED CATHODE MATERIAL PRECURSOR FROM RECYCLED LITHIUM-ION BATTERIES”, is a continuation-in-part of U.S. patent application Ser. No. 18/120,786, filed Mar. 13, 2023, entitled, “DOPED CATHODE MATERIAL FROM RECYCLED LITHIUM-ION BATTERIES”, and is a continuation-in-part of U.S. patent application Ser. No. 18/231,953, filed Aug. 9, 2023, entitled, “CURING PROCESS FOR SURFACE DEFECTS OF CATHODE MATERIAL”. This patent application also claims the benefit of U.S. Provisional Application No. 63/597,524, filed Nov. 9, 2023, entitled, “CATHODE MATERIALS FOR LI-ION BATTERIES” and U.S. Provisional Application No. 63/697,983, filed Sep. 23, 2024, entitled, “RECYCLED CATHODE MATERIALS FOR LI-ION BATTERIES”.

### BACKGROUND

Lithium-ion (Li-ion) batteries are a preferred chemistry for secondary (rechargeable) batteries in high discharge applications such as electrical vehicles (EVs) and power tools where electric motors are called upon for rapid acceleration. Li-ion batteries include a charge material, conductive powder and binder applied to or deposited on a current collector, typically a planar sheet of copper or aluminum. The charge material includes anode charge material, typically graphite or carbon, and cathode charge material, which includes a predetermined ratio of metals such as lithium, nickel, manganese, cobalt, aluminum, iron and phosphorous, defining a so-called “battery chemistry” of the Li-ion cells. The preferred battery chemistry varies between vendors and applications, and recycling efforts of Li-ion batteries typically adhere to a prescribed molar ratio of the battery chemistry in recycled charge material products. A purity of the constituent products is highly relevant to the quality and performance of the recycled cells, often relying on so-called “battery grade” materials, implying a 99.5% purity.

### SUMMARY

In the battery recycling process described herein for producing a doped cathode material, a recycling stream of comingled charge materials from cathodes and anodes, including electrolytes and binders, from exhausted, waste and/or scrap Li-ion batteries is aggregated (comminuted, for example, by grinding, shredding, etc.) to generate a recycled battery charge material, referred to as black mass. Leaching of the black mass with an aqueous acidic solution forms a leach solution having a ratio of metallic elements. This ratio in the leach solution is adjusted to a targeted or selected ratio with additional metal salts, and a first dopant is also added to the leach solution. The charge material metal salts in the selected ratio and the first dopant are coprecipitated from the leach solution, generally by pH adjustment, to form a doped charge material precursor, which is then sintered with a lithium salt and a second dopant to form a sintered doped cathode material. Optional comminution of the sintered cathode material forms the doped cathode material for use in a recycled battery.

Configurations herein are based, in part, on the observation that Li-ion battery recycling for EVs and other industries generate large quantities of charge material metals in the form of exhausted cathode charge material (cathode material). Unfortunately, conventional approaches to battery recycling suffer from the shortcoming that an unknown history and quality of these recycled cathode materials may vary performance of the resulting cathode material precursors as well as the cathode materials prepared from them. For example, surface properties of the cathode material precursors, such as cracking, as well as the cycle life of the cathode materials can vary depending on the source and properties of the recycled materials from which they are produced.

Accordingly, configurations herein substantially overcome performance issues including cycle life, surface cracking, and tap density by the addition of doping substances, particularly dopant salts, during the recycling of battery charge materials. The doping substance is typically a metal salt comprising a metal that is different from the metals of the recycled battery charge materials that is added in small quantities to a leach solution prior to formation (coprecipitation) of a cathode material precursor and optionally also added to the cathode material precursor prior to sintering of the charge material. A typical dopant salt may include magnesium or aluminum and has surprisingly been found to improve the surface morphology of the cathode material precursor and also to improve cycle life of the cathode material, meaning the number of times a battery may be recharged. The use of two doping salts in the recycling process surprisingly enables formation of a cathode active material having a single crystal morphology, a narrow particle size span, and a high tap density from coprecipitated cathode material precursor having a low tap density, such as precursor prepared using a continuous process, such as in a continuous stirred tank reactor (CSTR) or in a batch, including one used in a continuous mode.

In further detail, in some configurations herein, a doped cathode material precursor is prepared from a recycled lithium-ion battery stream based on a co-precipitated mixture of at least one dopant salt and metallic elements of a selected or predetermined ratio, obtained by leaching a black mass from the recycled lithium-ion battery stream with an aqueous acidic solution. Coprecipitation results in a dopant-containing granular form of charge material metals, typically in a hydroxide form, which can be used as a precursor (pCAM, precursor Cathode Active Material) for the formation of a cathode active material (CAM), usable in the manufacture of new/recycled batteries. Prior to coprecipitation, additional metal salts are provided to adjust the ratio of the metallic elements to a selected or targeted ratio, and the one or more dopant salts are added, either separately (prior to or subsequent to) or during the ratio adjustment for obtaining desired performance improvements. Additional dopant salts may also be added to the precipitated mixture. For example, from the precursor, a sintering process that incorporates lithium salts and another dopant salt can be used to generate the corresponding CAM. Thus, doped cathode active material precursors and doped cathode active materials are prepared from the recycled lithium-ion battery stream and include a sintered combination of ratio adjusted metal salts, one or more dopant salts, and lithium salts.

### BRIEF DESCRIPTION OF THE DRAWINGS

The foregoing and other features will be apparent from the following description of particular embodiments disclosed herein, as illustrated in the accompanying drawings in which like reference characters refer to the same parts throughout the different views.

The drawings are not necessarily to scale, emphasis instead being placed upon illustrating the principles of the invention.

FIG. 1 is a context diagram of a recycling environment suitable for use with configurations herein.

FIG. 2 is a flowchart of a particular embodiment for introduction of dopants for charge material performance improvements in the recycling process of FIG. 1.

FIGS. 3 and 4 are scanning electron micrographs (SEMs) depicting the surface morphology of charge material precursor particles resulting from the process of FIG. 2.

FIG. 5 is a graph of charge cycle improvements resulting from doping according to the flowchart of FIG. 2.

### DETAILED DESCRIPTION

Depicted below is an example method and approach for recycling batteries, such as NMC batteries. Li-ion batteries employ a so-called battery chemistry, which defines the types and ratios of metal ions used to form the cathode material; anode material is almost always a carbon or graphite-based formulation. Configurations herein employ an NMC battery chemistry as an example. However, the disclosed approach may be practiced with any suitable battery chemistry. The particular ratio is set by the manufacturer or recipient of the recycled charge material, and charge material and charge material precursor can be generated meeting the manufacturer prescribed specifications.

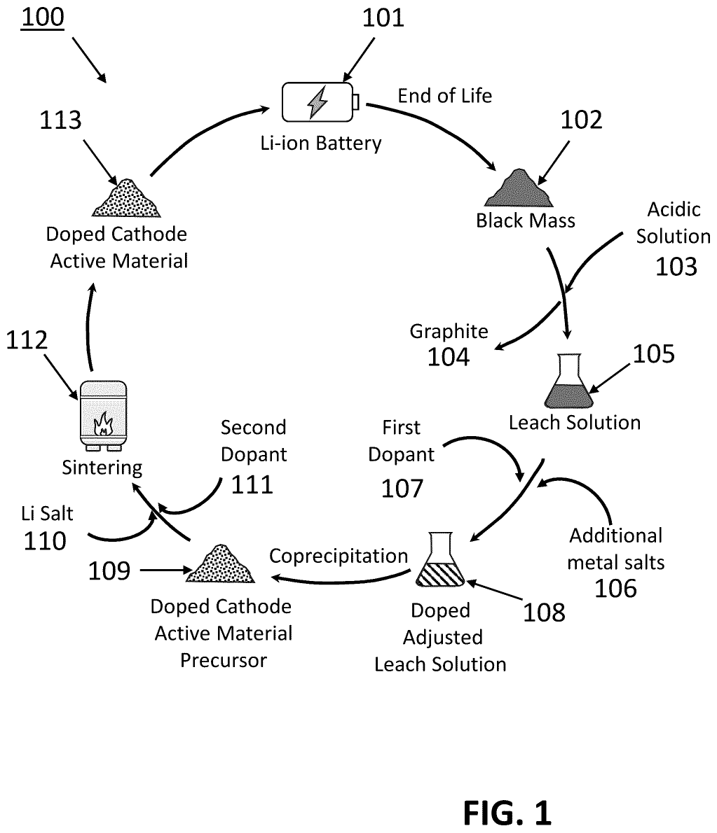

FIG. 1 is a context diagram of a recycling environment suitable for use with configurations herein. Referring to FIG. 1, a recycling scenario 100 begins with a deployed Li-ion battery 101, typically from an EV. Li-ion batteries 101 have a finite number of charge cycles before the ability of the charge material to accept sufficient charge degrades substantially. Add to this the batteries from premature end-of-life due to vehicle failure, collision damage, etc. This collective end-of-life recycling stream contributes to an abundant supply of exhausted batteries comprising spent cells and charge material. The batteries are discharged and agitated into a granular black mass 102 through physical grinding, shredding, and pulverizing, this black mass including the charge material and any incidental casing and current collectors of copper and aluminum. The black mass, including both cathode materials of cathode material metal salts and anode materials of carbon and graphite, and acidic solution 103 are combined to form a leach solution 105 of dissolved charge material metals from which insoluble materials are removed, such as graphite 104.

Leach solution 105 includes Ni, Mn and Co salts, such as sulfate salts from sulfuric acid leaching. However, other charge material metals and/or leach acid may be employed. Leach solution 105 has a molar ratio of Ni, Mn and Co based on the constituent composition of the incoming recycling stream. The molar ratio is adjusted as needed with additional metal salts, such as Ni, Mn, and Co sulfate salt (typically a virgin or control form of fresh materials). In addition, a first dopant 107 is also added to the leach solution to yield doped ratio-adjusted leach solution 108.

Coprecipitation in one or more vessels begins by adjusting the pH of the leach solution for precipitating the charge material metals (charge materials) in the desired ratio resulting from the adjustment. Sodium hydroxide or another strong base increases the pH of the leach solution and causes the leached metal salts (NMC salts) to fall out of solution with the first dopant to form doped cathode material precursor 109 in a granular form, separable by filtration, typically as hydroxides. This granular form precipitated from the pH adjustment of the leach solution defines the doped pCAM (cathode active material precursor) having the desired molar ratio of metals for a target battery chemistry for new, recycled batteries. Sintering in a furnace 112 with lithium salt 110 (such as lithium carbonate or other lithium salts) and second dopant 111 forms doped cathode active material 113 (CAM) for the recycled Li-ion battery. In an example configuration, doped cathode active material LiNiₓMn_{y}Co_{z}O₂ is synthesized by sintering the second dopant, NiₓMn_{y}Co_{z}(OH)₂, and Li₂CO₃, where x, y and z represent the respective molar ratios of Ni, Mn, and Co. Common chemistries include NMC 111, representing equal molar components of Ni, Mn, and Co, NMC 811, NMC 622 and NMC 532, however any suitable molar ratio may be achieved by the ratio adjustment in the leach solution, dual doping, and sintering. The recycled cathode material may then be merged back into the recycling stream as cathode material.

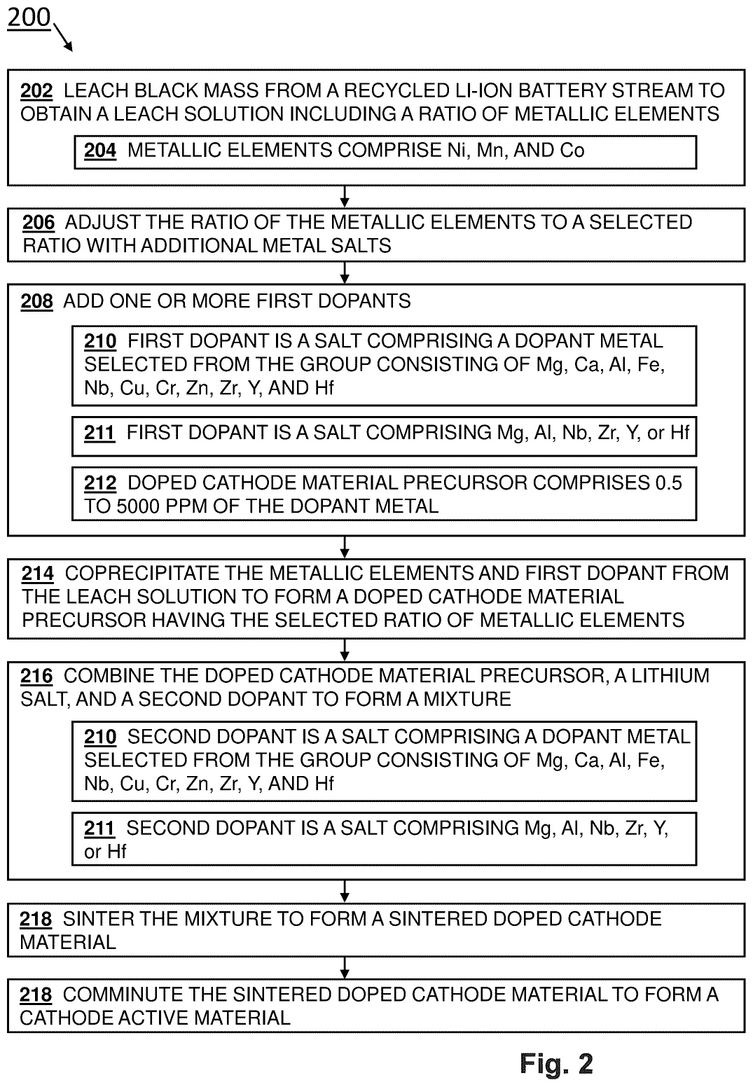

FIG. 2 is a flowchart 200 for introduction of dopants for obtaining charge material having performance improvements in the recycling process of FIG. 1. The dopants are salts included in relatively small amounts added into the leach solution for coprecipitation. Optionally, additional dopants may also be introduced into the lithium mixture for sintering.

Referring to FIGS. 1 and 2, the method of producing a doped cathode material from a recycled lithium-ion battery stream includes, at step 202, leaching a black mass from the recycled lithium-ion battery stream to obtain a leach solution including a ratio of metallic elements. Following impurity removal, such as by filtration, the leach solution is a substantially pure composition of metallic elements including, for example, nickel, manganese, and cobalt, as depicted at step 204. Other cathode material metals may also be dissolved, depending on the source of the recycled battery stream. Anode material is generally undissolved graphite after leaching at 202 and can be removed by filtration as the substantially pure leach solution is drawn off. Separate recycling of the residual anode material may also be performed. The ratio of the metallic elements is adjusted to a selected ratio with additional metal salts to correspond to a selected or desired cathode material ratio, which often corresponds to a targeted recycled battery chemistry, as shown at step 206.

One or more first dopants are also added to the leach solution. Doping may be performed with a number of materials, usually water-soluble salts, and in various concentrations, to achieve performance improvements, referring to step 208. The first dopant is added to the leach solution prior to coprecipitation.

Thus, the addition of the first dopant salt is followed by coprecipitation of the metallic elements and the first dopant from the leach solution to form a doped cathode material precursor having the selected ratio of metallic elements, as disclosed at step 214. Coprecipitation involves adjusting the pH (raising) to draw the comingled charge materials out of solution in the adjusted ratio including the first dopant salt.

In an example configuration, the first dopant is a salt comprising a dopant metal selected from the group consisting of Mg, Ca, Al, Fe, Nb, Cu, Cr, Zn, Zr, Y, and Hf, as shown at step 210. Preferably, the first dopant is a salt comprising Mg, Al, Nb, Zr, Y, or Hf, as shown at step 211. This results in a doped cathode material precursor having between 0.5 and 5000 ppm of the dopant metal, as depicted at step 212.

Specific examples of the concentrations (in ppm) for particular first dopant salts are shown below in Table 1:

TABLE 1

| | Amt Dopant Salt in Cathode |
|---|---|
| Salt | Precursor (ppm) |
| Mg | 50-2000 |
| Ca | 20-5000 |
| Al | 1-6000 |
| Fe | 1-1000 |
| Cu | 1-300 |
| Cr | 1-300 |
| Zn | 1-300 |
| Zr | 0.5-2000 |
| Nb | 1-3000 |

Surprisingly, it has been found that incorporation of low levels of various types of dopant salts prior to coprecipitation results in the formation of doped cathode material precursors having significantly improved properties. In particular, it is believed that doping of the leach solution provides relief of the internal particle stresses present in the forming cathode material precursors, resulting in precursor particles having significantly improved physical and surface properties. Benefits to the particle morphology include fewer cracks than a comparative cathode material precursor prepared without addition of the dopant salt to the leach solution prior to co-precipitation.

The amount of cracking can be evaluated using any method known in the art. For example, the doped cathode material precursor has been found to have a BET surface area value that is lower than a BET value of a comparative cathode material precursor prepared without the addition of the first dopant salt to the leach solution prior to coprecipitation. The BET value of the doped cathode material precursor may be 2-3 times lower than the BET value of the comparative cathode material precursor.

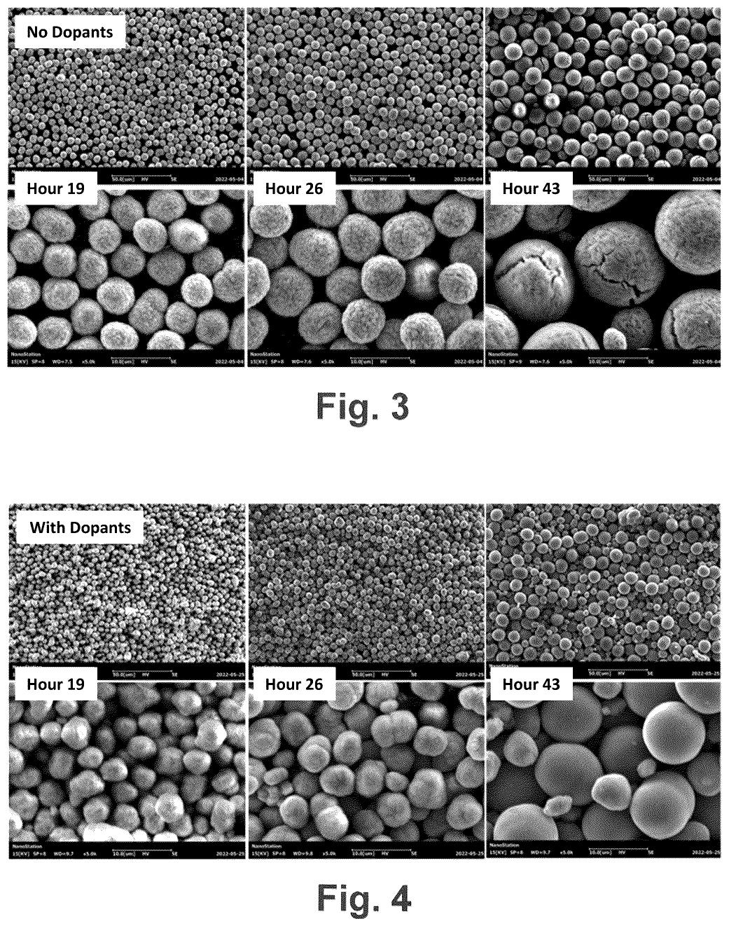

Surface morphology can also be assessed by microscopy. Specific evaluation results are shown in FIGS. 3 and 4, which are SEM (scanning electron micrograph) images depicting surface morphology of charge material precursor particles resulting from the dopant method described in FIG. 2. FIG. 3 shows a control group of undoped charge material particles at various times during the coprecipitation process. By comparison, FIG. 4 shows formation of the doped charge material precursor particles of the present disclosure in which dopant salts have been added prior to coprecipitation. In this specific example, the process includes the addition of aluminum nitrate salt to the nickel manganese cobalt sulfate solution prior to coprecipitation.

As shown, surface cracking is significantly reduced, which is believed to be a result of internal stress release provided by the first dopant salt during particle growth and, consequently, prevention of particle cracking. In FIG. 4, the well-defined and continuous particle surface in a single crystal form can be seen, with a notable improvement over visible cracks seen in FIG. 3. Thus, the doped cathode material precursor particles have been found to have fewer visible cracks within a single precursor particle. In addition, fewer precursor particles that are formed have been found to have any visible cracks. Preferably, less than 10%, more preferably less than 5%, and most preferably less than 1% of the resulting doped cathode material precursor particles have cracks.

In particular configurations, the doped cathode material precursor comprises greater than 60 mole % nickel, as a high nickel cathode material has been found to particularly benefit from the doping process. This includes NMC 622 and NMC 811. Other configurations with lower nickel also benefit, as when the doped cathode material is less than or equal to 60 mole % nickel, including from 10-50 mole % nickel, such as NMC 532. In a particularly preferred configuration, the doped cathode material precursor comprises 30-70 mole % nickel, such as 40-60 mole % nickel.

Furthermore, the doped pCAM has also been found to improve the lattice structure resulting in the sintered CAM, thereby improving charge cycle performance. For example, the doped cathode material precursor and lithium salts can be combined, optionally with a second dopant, to form a mixture, as depicted at step 216 of FIG. 2, and the mixture is then sintered to form the sintered doped cathode material, as shown at step 218. Following sintering, the doped cathode material is received to be harvested and/or evaluated. In particular, the sintered doped cathode material may be comminuted or otherwise deagglomerated to form a doped cathode material, as depicted at step 220. In some embodiments, a second sintering step can be performed, after the first sintering step or after the comminution, which may further improve particle properties and/or performance. For example, mechanical deagglomeration may sometimes form a material having surface defects, such as surface roughness and/or cracking. A second sintering process, sometimes referred to as a curing or heat treatment process, can be used to form a cathode material having fewer surface defects.

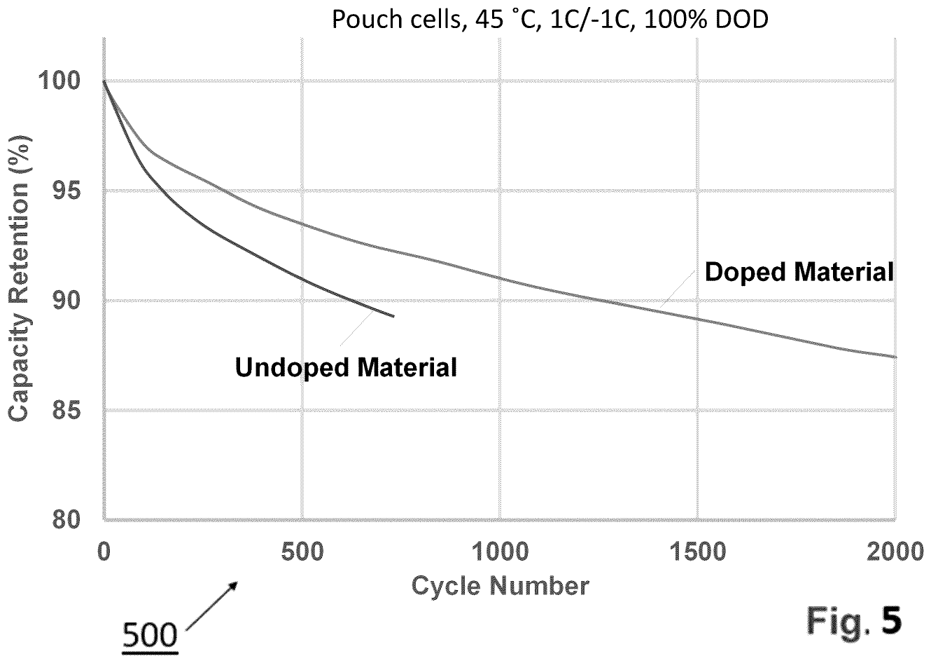

FIG. 5 is a graph 500 of charge cycle improvements resulting from doping according to the flowchart of FIG. 2, using a first dopant salt only. In FIG. 5, capacity retention refers to a percentage of a full charge remaining after a number of charge/discharge cycles, shown by the charge index. It has been surprising found that the inclusion of a dopant salt prior to coprecipitation to form a doped charged material precursor also significantly improves the cycle life of a doped charged material prepared from it. For example, doping of a relatively small amount of Mg, on the order of 300 ppm, improved cycling performance, retaining greater than 90% of full charge after approximately 1240 cycles and 80% of full charge capacity after approximately 5000 cycles. Other doping salts may also be employed to provide similar or improved performance.

In specific configurations, the first dopant salt is a Mg salt or an Al salt. For example, a particular arrangement is a doped cathode material precursor having between 1-100 ppm of an Al dopant salt. In another example, the first dopant salt is a Mg salt to produce a Mg-doped cathode material precursor having from 150-450 ppm Mg. In still other arrangements, the first dopant salt is a Li salt and the doped cathode material precursor has <0.01 ppm of Li. Note that the Li dopant is added at the leaching phase, prior to coprecipitation, and should not be confused with lithium carbonate added for sintering of the precipitated material.

As noted above, optionally a second dopant salt may also be added to the coprecipitated mixture prior to sintering with lithium salts (typically lithium carbonate). For example, as shown in step 216 of FIG. 2, in a particular embodiment, the doped cathode material precursor, a lithium salt, and a second dopant may be combined to form a mixture that is subsequently sintered and comminuted. It has surprisingly been found that inclusion of a second dopant salt prior to sintering, in combination with a first dopant salt prior to coprecipitation, leads to a doped cathode material having a preferred single crystal morphology, a narrow particle size span, and a high tap density from coprecipitated cathode material precursor having a low tap density, such as precursor prepared in CSTR or batch reactors.

For example, most cathode active material (CAM), particularly CAM having from 40-60 mole % nickel (often referred to as of the mid-Ni CAM) in the market is produced from a narrow span, high tap density precursor (pCAM) that is best achieved in a batch-type coprecipitation process. The narrow span, high tap density pCAM is desirable since it is believed to contribute to the formation of CAM having a single crystal morphology along with a narrow span that enhances tap density. However, the production throughput of batch reactions is relatively low. Furthermore, continuous processes are known to lead to precursor material having a low tap density.

In embodiments of the process described herein, it has surprisingly been found that a mid-Ni CAM precursor having a low tap density prepared from a continuous coprecipitation process, such as in a continuous stirred tank reactor (CSTR-type precursor) can be sintered with a lithium salt and a second dopant salt resulting in a mid-Ni CAM having a good single crystal morphology and also having a high tap density, such as >1.6 g/cc, including >2.0 g/cc. Thus, surprisingly, a high tap density single crystal cathode material can be prepared from a low tap density cathode precursor. This enables the use of a continuous reactor to prepare the precursor, dramatically increasing the throughput of precursor production and lowering the cost of the overall process.

For example, a mid-Ni cathode material precursor (pCAM), such as NMC532 was prepared by leaching an NMC black mass from recycled lithium ion (Li-ion) batteries with an aqueous acidic solution comprising sulfuric acid followed by filtration of the solid phase, which is primarily graphite. The ratio of metals in the leach solution was determined and adjusted as needed to achieve the target ratio of Ni:Mn:Co of 5:3:2. Magnesium sulfate was added to this ratio-adjusted leach solution as a first dopant. The dopant-containing solution was then coprecipitated in a continuous stirred tank reactor to form a magnesium doped cathode material precursor having 150-450 ppm Mg (such as 300 ppm) and having the desired ratio of NMC metallic elements. The D50 particle size was measured to be between 3.0 and 7.0 μm and the particle size span was between 0.9 and 1.5. In addition, the Mg-doped pCAM was found to have a relatively low tap density that was between 1.4 and 2.0 g/cc.

The doped cathode material precursor, lithium carbonate, and zirconium oxide (a second dopant) are combined to form a mixture. The ratio of components can vary as needed to produce doped cathode material have desirable overall properties. For example, 1 kg of Mg-doped pCAM, 0.42 kg of lithium carbonate (Li/NMC molar ratio of 1.05), and 4.44 g of zirconium oxide can be combined and sintered at a temperature of from 500° C. to 1300° C., such as from 700° C. to 1200° C. or 900°° C. to 1100° C. or in air for 7-30 hours to form a Zr-doped sintered Mg-doped CAM having a single crystal morphology. After crushing an and milling, this sintered doped cathode material was found to have a particle size in the range 3.0 to 7.0 μm. Surprisingly, the product was also found to have a higher tap density than the doped pCAM that was sintered. For example, the cathode material has a tap density of >1.6 g/cc, more preferably >1.9 g/cc, and most preferably >2.0 g/cc. Good cycle life and good thermal stability also resulted.

While the system and methods defined herein have been particularly shown and described with references to embodiments thereof, it will be understood by those skilled in the art that various changes in form and details may be made therein without departing from the scope of the invention encompassed by the appended claims.

1. A method of producing a doped cathode material from a recycled lithium-ion battery stream, the method comprising:
leaching a black mass from the recycled lithium-ion battery stream with an aqueous acidic solution to obtain a leach solution having a ratio of metallic elements,
adjusting the ratio of the metallic elements to a selected ratio with additional metal salts,
adding a first dopant to the leach solution,
co-precipitating the metallic elements in the selected ratio and the dopant from the leach solution to form a doped cathode material precursor having the selected ratio of metallic elements,
combining the doped cathode material precursor, a second dopant, and a lithium salt to form a mixture,
sintering the mixture to form a sintered doped cathode material, and
comminuting the sintered cathode material to form the doped cathode material.

2. The method of claim 1, wherein the doped cathode material precursor, the doped cathode material, or both have a single crystal structure.

3. The method of claim 1, wherein the metallic elements are nickel, manganese, and cobalt.

4. The method of claim 1, wherein the doped cathode material precursor comprises 30-70 mole % nickel.

5. The method of claim 4, wherein the doped cathode material precursor comprises 40-60 mole % nickel.

6. The method of claim 1, wherein the first dopant is a dopant metal salt comprising Al, Mg, Nb, Zr, Y, or Hf.

7. The method of claim 1, wherein the second dopant is a dopant metal oxide comprising Al, Mg, Nb, Zr, Y, or Hf.

8. The method of claim 1, wherein the first dopant and the second dopant comprise different metals.

9. The method of claim 1, wherein the first dopant is a dopant metal salt comprising Mg and the second dopant is a dopant metal oxide comprising Zr.

10. The method of claim 1, wherein the doped cathode material precursor has a particle size of 3-7 μm.

11. The method of claim 1, wherein the doped cathode material precursor has a tap density of 1.4-2.0 g/cc.

12. The method of claim 1, wherein the doped cathode material precursor has a particle span of greater than or equal to 1.0.

13. The method of claim 10, wherein the cathode material has a particle size of 3-7 μm.

14. The method of claim 1, wherein the cathode material has a tap density of >1.6 g/cc.

15. The method of claim 14, wherein the cathode material has a tap density of >2.0 g/cc.

16. The method of claim 1, wherein the mixture of the doped cathode material precursor, the second dopant, and the lithium salt is sintered at a sintering temperature of about 700° C. to about 1200° C.

17. The method of claim 16, wherein the sintering temperature is about 900° C. to about 1100° C.

18. The method of claim 1, wherein the lithium salt is lithium carbonate or lithium hydroxide.

19. The method of claim 1, wherein comminuting the sintered cathode material comprises crushing the sintered cathode material to form a crushed cathode material and milling the crushed cathode material to form the cathode active material.

20. The method of claim 19, wherein the crushed cathode material has a particle size of <1 mm.
